(19) United States
(12) Patent Application Publication
(10) Pub. No.: US 2026/0227429 A1
(43) Pub. Date: Aug. 6, 2026

(54) APPARATUS FOR MEASURING THE INTENSITY OF A CURRENT FLOW ALONG AN ELONGATED ELECTRICAL CONDUCTOR AND METHOD FOR COMPENSATING AN INFLUENCE OF THE POSITION OF THE ELONGATED ELECTRICAL CONDUCTOR ON THE MEASUREMENT

(71) Applicant: WAGO Verwaltungsgesellschaft mbH, Minden (DE)

(72) Inventor: Tristan NENTWIG, Bueckeburg (DE)

(73) Assignee: WAGO Verwaltungsgesellschaft mbH, Minden (DE)

(21) Appl. No.: 19/651,091

(22) Filed: Apr. 17, 2026

Related U.S. Application Data
(63) Continuation of application No. PCT/EP2024/078427, filed on Oct. 9, 2024.

(30) Foreign Application Priority Data
Oct. 19, 2023 (DE) 10 2023 128 826.1

(51) Int. Cl. G01R 15/14; G01R 19/00; G01R 35/00

(52) U.S. Cl. CPC G01R 15/148; G01R 19/0092; G01R 35/005

(57) ABSTRACT

An apparatus for measuring the intensity of a current flow along an elongated electrical conductor and a method for compensating for the influence of the position of the elongated electrical conductor on the measurement are provided. Magnetic field strengths are measured at two positions offset from each other substantially parallel to the axis of mirror symmetry and the magnetic field strengths are used to compensate for the influence of an offset of the elongated electrical conductor substantially parallel to the axis of mirror symmetry on the measurement

This nonprovisional application is a continuation of International Application No. PCT/EP2024/078427, which was filed on October 9, 2024, and which claims priority to German Patent Application No. 10 2023 128 826.1, which was filed in Germany on October 19, 2023, and which are both herein incorporated by reference.

### BACKGROUND OF THE INVENTION

### Field of the Invention

The present disclosure relates to an apparatus for measuring the intensity of a current flow along an elongated electrical conductor (e.g., an electrical wire, a busbar, etc.) and a method for compensating for the influence of the position of the elongated electrical conductor on the measurement.

### Description of the Background Art

When measuring the intensity of a current flow along an elongated electrical conductor using a magnetic field sensor, the accuracy of the measurement may depend on the position of the elongated electrical conductor relative to the magnetic field sensor.

### SUMMARY OF THE INVENTION

It is therefore the object of the present invention to disclosure is directed at taking an actual relative position into account and thereby alleviating the requirement of ensuring a predetermined (desired) relative position.

A method for compensating for an influence of a position of an elongated electrical conductor on a measurement of an intensity of a current flow along the elongated electrical conductor by a magnetic field sensor may comprise providing a magnetically permeable structure (e.g., a permanent magnet) surrounding the elongated electrical conductor. The cross-section of the magnetically permeable structure may exhibit an axis of mirror symmetry, or the cross-section of the magnetically permeable structure may exhibit an axis of mirror symmetry at least in an area around the electrical conductor. A longitudinal axis of a section of the elongated electrical conductor surrounded by the permeable structure may be perpendicular to the axis of mirror symmetry. The method may further comprise measuring magnetic field strengths at two positions offset from each other parallel to the axis of mirror symmetry and using the magnetic field strengths to compensate for the influence of an offset of the elongated electrical conductor parallel to the mirror symmetry axis on the measurement of the intensity of the current flow along the elongated electrical conductor.

In this regard, the term “magnetically permeable structure”, may refer to a structure made of a magnetically permeable material, for example, a structure made of a ferromagnetic material such as mu-metal. Furthermore, a magnetically permeable structure “surrounding the elongated electrical conductor”, may refer to a magnetically permeable structure having a concave region through which the elongated electrical conductor extends.

Furthermore, a magnetically permeable structure “whose cross-section has an axis of mirror symmetry at least in an area around the electrical conductor”, may refer to a magnetically permeable structure the cross-section of which comprises a section through which the electrical conductor extends and which is mirror-symmetric to an axis of mirror symmetry. The section may be rectangular, square, oval, or circular. The electrical conductor may extend through a center of the section. The axis of mirror symmetry may (essentially) pass through a center of the magnetically permeable structure.

Furthermore, the wording “to compensate for the influence of an offset of the elongated electrical conductor parallel to the axis of mirror symmetry on a measurement of the intensity of the current flow along the elongated electrical conductor”, may refer to the use of a correction factor which allows measured field strengths to be mapped to current intensities obtained, for example, through calibration measurements. Multiple calibration measurement series may be provided, with each series being based on a different offset and each series including different current intensities. By selecting the most fitting calibration measurement series, the magnitude of the correction factor may be reduced.

The area of the cross-section around the elongated electrical conductor which has an axis of mirror symmetry may comprise more than 50%, more than 75% or more than 90% of a cross-sectional area of the magnetically permeable structure. If the area comprises 100% of the cross-sectional area of the magnetically permeable structure, the cross-section of the (entire) magnetically permeable structure has an axis of mirror symmetry.

The magnetically permeable structure may encircle the elongated electrical conductor only partially.

This may allow attaching the magnetically permeable structure without (temporarily) interrupting an electrical line formed by the electrical conductor.

The magnetically permeable structure may have a U-shaped cross-section.

The magnetically permeable structure may be provided with a housing. The cross-section of the housing may have a V-shaped recess and the elongated electrical conductor may extend through the V-shaped recess.

The V-shaped recess may facilitate centering the electrical conductor in the magnetically permeable structure by pressing the electrical conductor towards the tapered end of the recess.

When producing calibration measurement series, an insert with one or more guides (e.g., one or more openings) may be put into the U-shaped or V-shaped recess with the one or more guides specifying an offset of an elongated electrical conductor extending through the recess parallel (and perpendicular) to the axis of mirror symmetry.

The method may further comprise measuring magnetic field strengths at two positions which are mirror-symmetrical with respect to the axis of mirror symmetry and using the magnetic field strengths to compensate for the influence of an offset of the elongated electrical conductor perpendicular to the axis of mirror symmetry on the measurement.

This may allow for accurate measurements even without centering the electrical conductor.

The method may further comprise compensating for the influence of magnetic interference fields by adding each of the magnetic field strengths at the two positions offset from each other parallel to the axis of mirror symmetry with a magnetic field strength at the respective mirror-symmetric position.

For example, there may be two pairs of mirror-symmetrically arranged sensors, and by adding the magnetic field strengths per pair, the influence of interfering fields on the detection of the offset of the electrical conductor parallel to the axis of mirror symmetry may be reduced.

An apparatus or measuring the intensity of a current flow along an elongated electrical conductor may comprise a magnetically permeable structure surrounding the elongated electrical conductor. A cross-section of the magnetically permeable structure may exhibit an axis of mirror symmetry or the cross-section of the magnetically permeable structure may exhibit an axis of mirror symmetry at least in an area around the elongated electrical conductor. A longitudinal axis of a section of the elongated electrical conductor surrounded by the magnetically permeable structure may be perpendicular to the axis of mirror symmetry. The apparatus may comprise a first magnetic field sensor and a second magnetic field sensor, wherein the magnetic field sensors are arranged parallel to the axis of mirror symmetry or are arranged mirror-symmetrically with respect to the axis of mirror symmetry.

The measured values of the magnetic field sensors may be used not only to take into account an offset of the elongated electrical conductor perpendicular to the axis of mirror symmetry, but also to compensate for disturbances when taking into account the offset of the elongated electrical conductor parallel to the axis of symmetry. If there is an offset perpendicular to the axis of mirror symmetry and an offset parallel to the axis of mirror symmetry, both may be taken into account when measuring the intensity of the current.

The area of the cross-section around the elongated electrical conductor which has an axis of mirror symmetry may comprise more than 50%, more than 75% or more than 90% of a cross-sectional area of the magnetically permeable structure.

The magnetically permeable structure may encircle the elongated electrical conductor only partially.

The magnetically permeable structure may have a U-shaped cross-section.

The magnetically permeable structure may be provided with a housing. The cross-section of the housing may have a V-shaped recess, and the elongated electrical conductor may extend through the V-shaped recess.

The magnetic field sensors may be configured to measure a magnetic field strength perpendicular to a surface of the magnetically permeable structure facing the elongated electrical conductor.

The apparatus may comprise a third magnetic field sensor. The first magnetic field sensor and the second magnetic field sensor may be arranged in a mirror-symmetrical manner with respect to the axis of mirror symmetry. The third magnetic field sensor may be offset relative to the first magnetic field sensor parallel to the axis of mirror symmetry.

The apparatus may comprise a fourth magnetic field sensor. The third magnetic field sensor and the fourth magnetic field sensor may be arranged in a mirror-symmetrical manner with respect to the axis of mirror symmetry. The fourth magnetic field sensor may be offset relative to the second magnetic field sensor parallel to the axis of mirror symmetry.

The apparatus may comprise a fifth magnetic field sensor. The fifth magnetic field sensor may be offset relative to the first and third magnetic field sensors parallel to the axis of mirror symmetry.

The apparatus may comprise a sixth magnetic field sensor. The fifth magnetic field sensor and the sixth magnetic field sensor may be arranged in a mirror-symmetrical manner with respect to the axis of mirror symmetry. The sixth magnetic field sensor may be offset relative to the second and fourth magnetic field sensor parallel to the axis of mirror symmetry.

By using the measured values of the pairs, the influence of interfering fields on the detection of the offset of the elongated electrical conductor parallel to the axis of mirror symmetry may be reduced.

Notably, all features described in connection with the apparatus may also be features of the method and vice versa.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic representation of an apparatus according to an example;

FIG. 2 shows a schematic representation of an apparatus according to an example;

FIG. 3 shows a schematic representation of an apparatus according to an example;

FIG. 4 shows a schematic representation of an apparatus according to an example;

FIG. 5 shows a schematic representation of an apparatus according to an example;

FIG. 6 shows a schematic representation of an apparatus according to an example;

FIG. 7 shows a flowchart of a method for compensating for an influence of a position of an elongated electrical conductor on a measurement of an intensity of a current flow along the elongated electrical conductor by a magnetic field sensor;

FIG. 8 shows an exemplary curve for determining an offset of the elongated electrical conductor parallel to the axis mirror symmetry;

FIG. 9 shows an exemplary curve for compensating for the influence of the offset of the elongated electrical conductor parallel to the axis of mirror symmetry on the measurement;

FIG. 10 shows an exemplary curve for determining an offset of the elongated electrical conductor perpendicular to the axis mirror symmetry; and

FIG. 11 shows an exemplary curve for compensating for the influence of the offset of the elongated electrical conductor perpendicular to the axis of mirror symmetry on the measurement.

### DETAILED DESCRIPTION

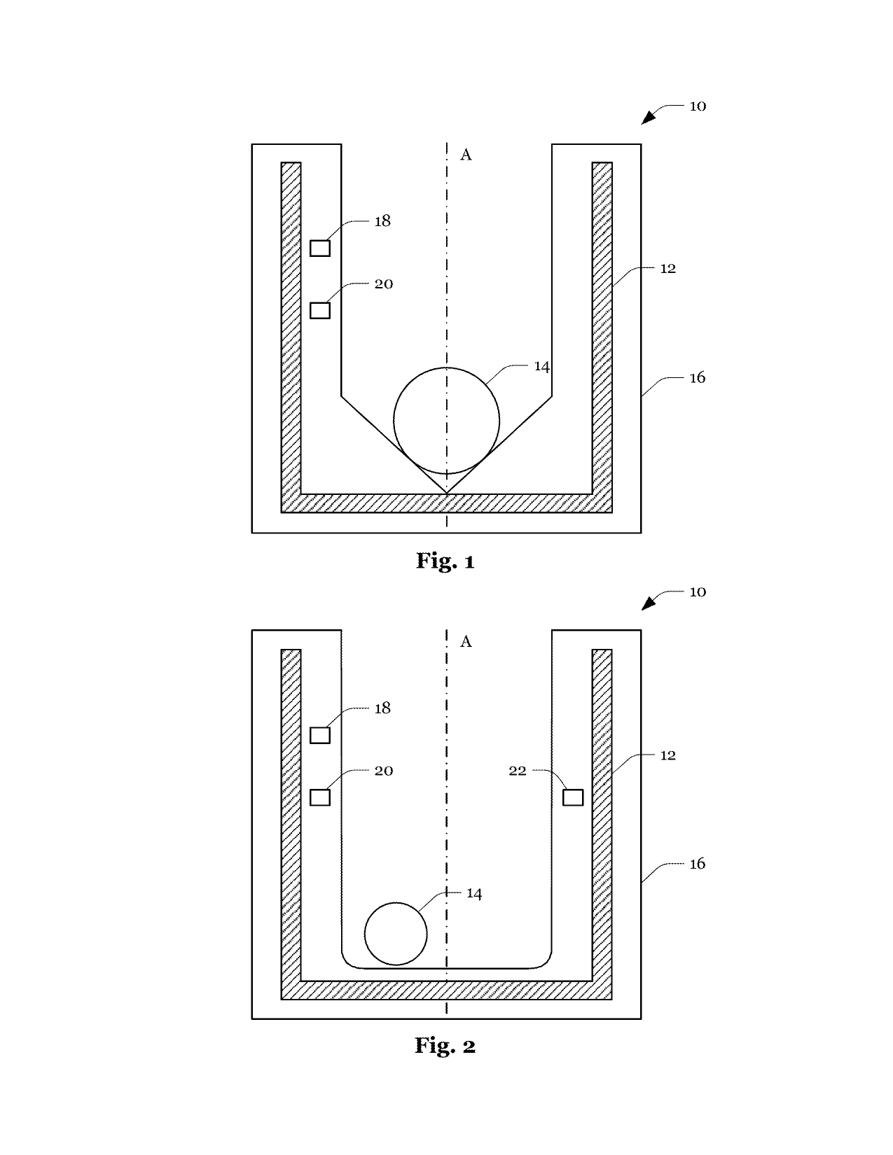

FIG. 1 shows a cross-sectional view of an apparatus 10. The apparatus 10 comprises a magnetically permeable structure 12. The magnetically permeable structure 12 surrounds an elongated electrical conductor 14, which has a circular cross-section. Notably, the invention is not limited to elongated electrical conductors 14 with circular cross-sections. For example, the elongated electrical conductor 14 may have a triangular or square cross-section.

The magnetically permeable structure 12 has a U-shaped cross-section. The U-shaped cross-section exhibits an axis A of mirror symmetry, which is perpendicular to a longitudinal axis of the electrical conductor 14. The magnetically permeable structure 12 is further provided with a housing 16. The cross-section of the housing 16 comprises a V-shaped recess through which the electrical conductor 14 extends. This centers the electrical conductor 14 relative to the legs of the magnetically permeable structure 12.

The apparatus 10 further comprises two magnetic field sensors 18 and 20, which are offset from each other parallel to the axis A of mirror symmetry. The field strength measured in the horizontal direction by the magnetic field sensors 18 and 20 depends on the diameter of the elongated electrical conductor 14. This allows determining the offset of the center of the elongated electrical conductor 14 along the axis A of mirror symmetry in relation to the offset on which the nearest available calibration curve is based. The values of the calibration curve may then be used to determine the intensity of the current flow through the elongated electrical conductor 14 by applying a correction factor.

As indicated in FIG. 2, the recess may also be U-shaped and the lack of a device for centering the elongated electrical conductor 14 may be compensated for by providing an additional sensor 22, where the magnetic field sensors 20 and 22 are arranged in a mirror-symmetrical manner with respect to the axis A of mirror symmetry. The field strengths measured by the magnetic field sensors 20 and 22 perpendicular to the surface of the magnetically permeable structure 12 will only be equal if the elongated electrical conductor 14 extends through the axis A of mirror symmetry.

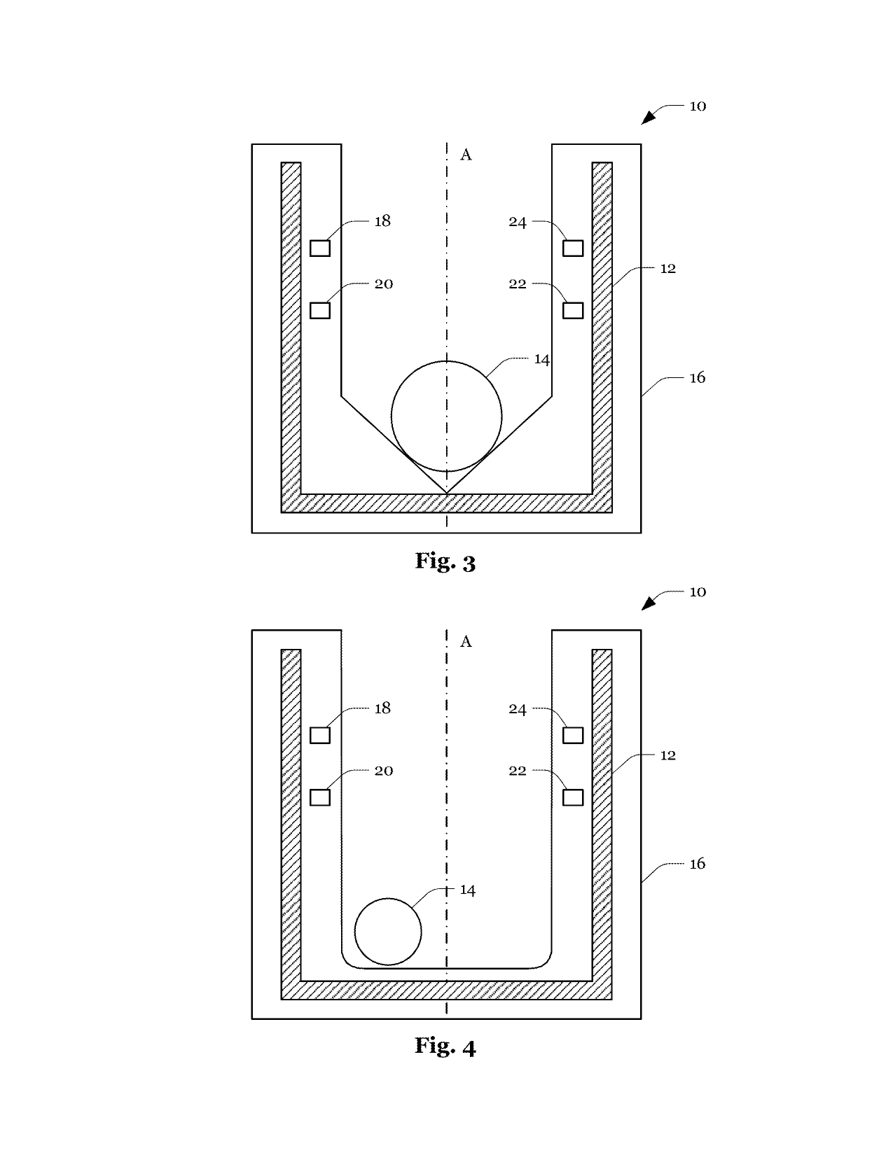

As shown in FIG. 3 and FIG. 4, the apparatus 10 shown in FIG. 1 and FIG. 2 may be provided with two further magnetic field sensors 22 and 24 and one further magnetic field sensor 24, respectively. This may result in two pairs of magnetic field sensors 18 and 20 and 24 and 22, respectively, which are offset from each other parallel to the axis A of mirror symmetry, with the magnetic field sensors 18 and 20 and 24 and 22, respectively, of each pair being arranged in a mirror-symmetrical manner with respect to the axis A of mirror symmetry. By using the measured values of the magnetic field sensor pairs 18 and 20 and 24 and 22, respectively, the influence of interfering fields on the detection of the offset of the elongated electrical conductor 14 parallel to the axis A of mirror symmetry may be reduced.

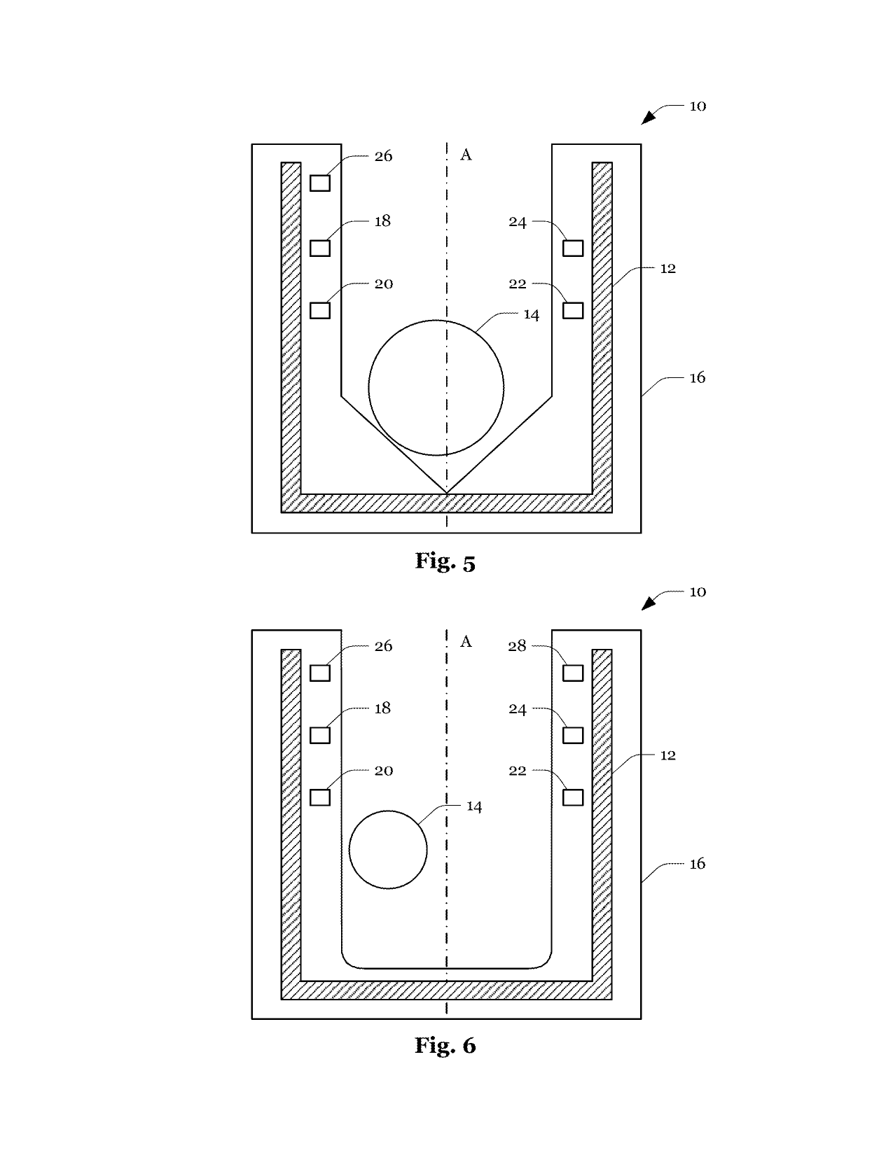

As shown in FIG. 5 and FIG. 6, further magnetic field sensors 26 and 28 may be provided, which may further decrease the requirements with respect to positioning of the electrical conductor 14 and/or may further increase the robustness against the influence of magnetic interference fields.

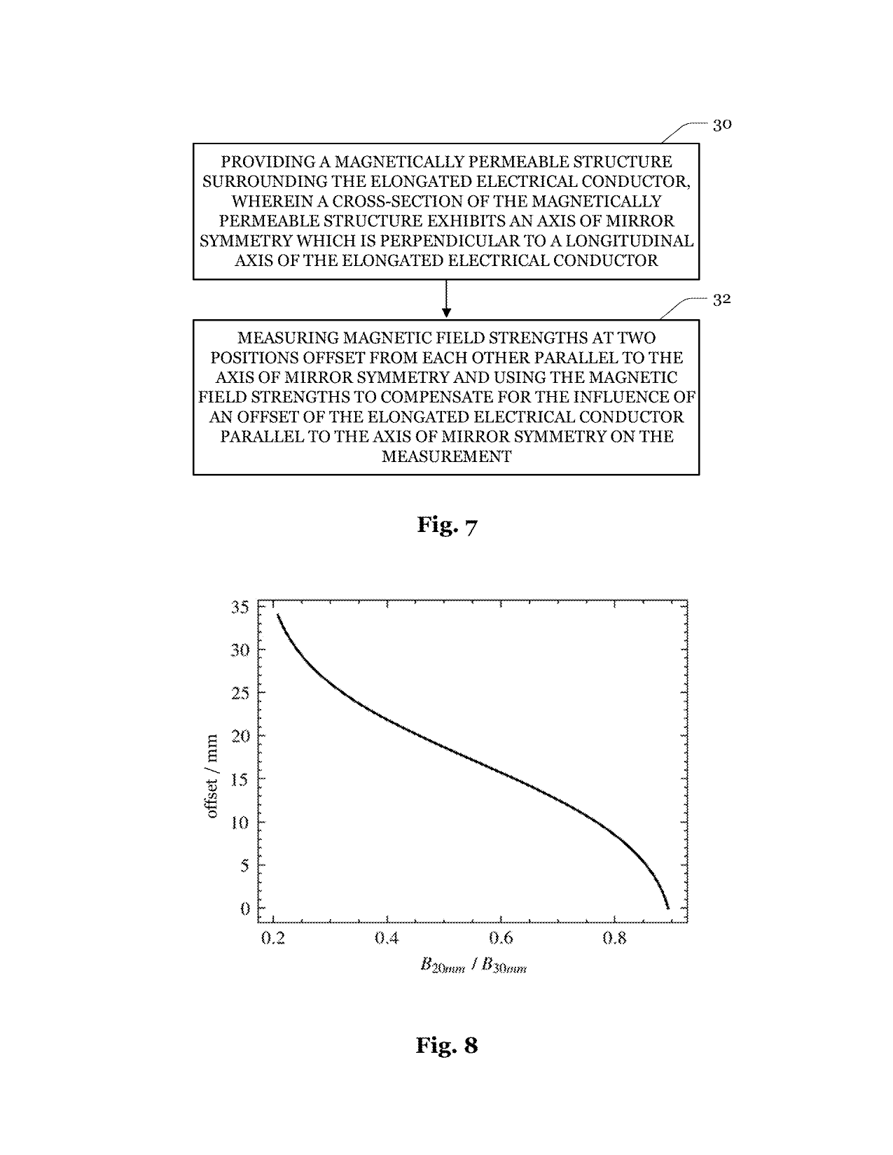

FIG. 7 shows a flowchart of a method. The method may start in step 30 with providing a magnetically permeable structure 12 surrounding the elongated electrical conductor 14, wherein a cross-section of the magnetically permeable structure 12 exhibits the axis A of mirror symmetry which is perpendicular to a longitudinal axis of the elongated electrical conductor 14. The method may then be continued in step 32 with measuring magnetic field strengths at two positions offset from each other parallel to the axis A of mirror symmetry and using the magnetic field strengths to compensate for the influence of an offset of the elongated electrical conductor 14 parallel to the axis A of mirror symmetry on the measurement.

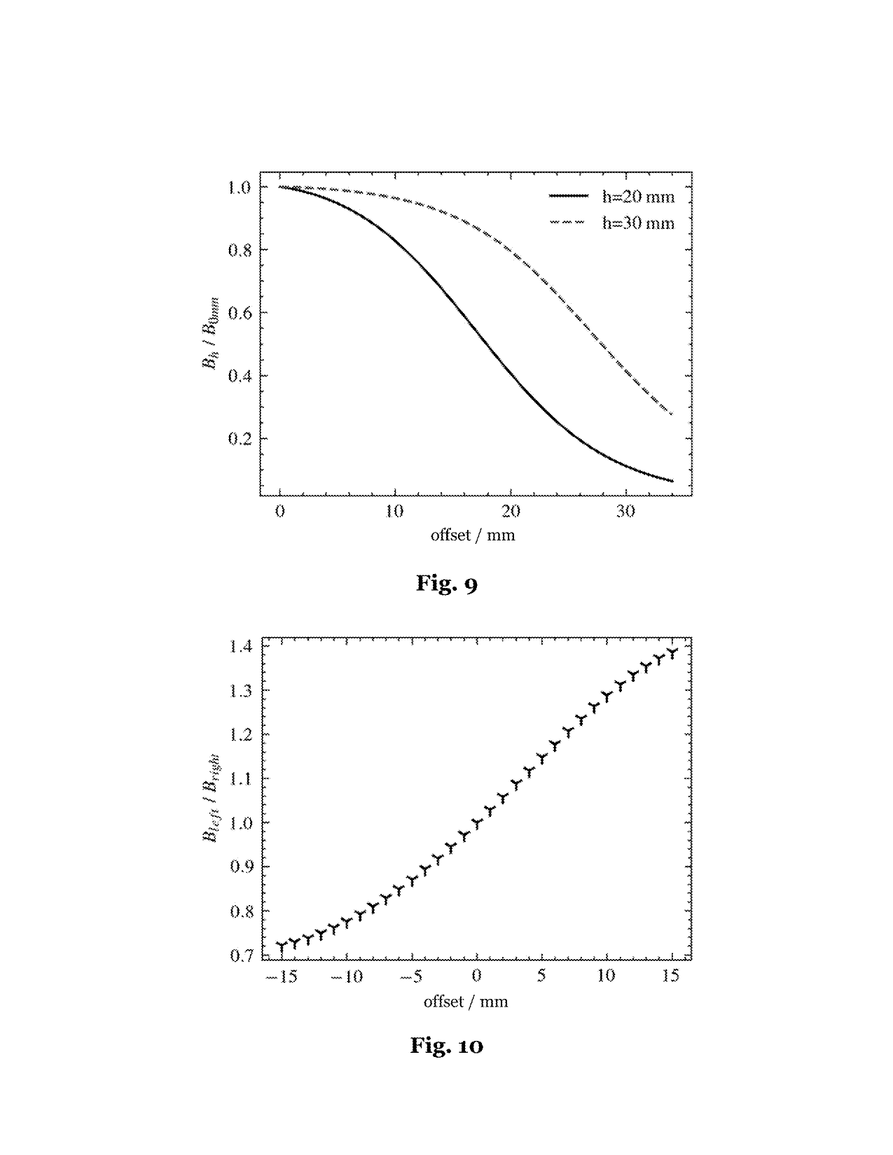

In FIG. 8, the offset of the elongated electrical conductor 14 parallel to the axis A of mirror symmetry is plotted against the ratio of the magnetic field strengths at two positions offset parallel to the axis A of mirror symmetry for an exemplary apparatus 10. The offset may therefore be determined from the ratio of the magnetic field strengths at the two positions offset parallel to the axis A of mirror symmetry. Based on the offset, a correction factor may be determined, as shown in FIG. 9. By applying the correction factor to one of the magnetic field strengths, a corrected magnetic field strength may be determined.

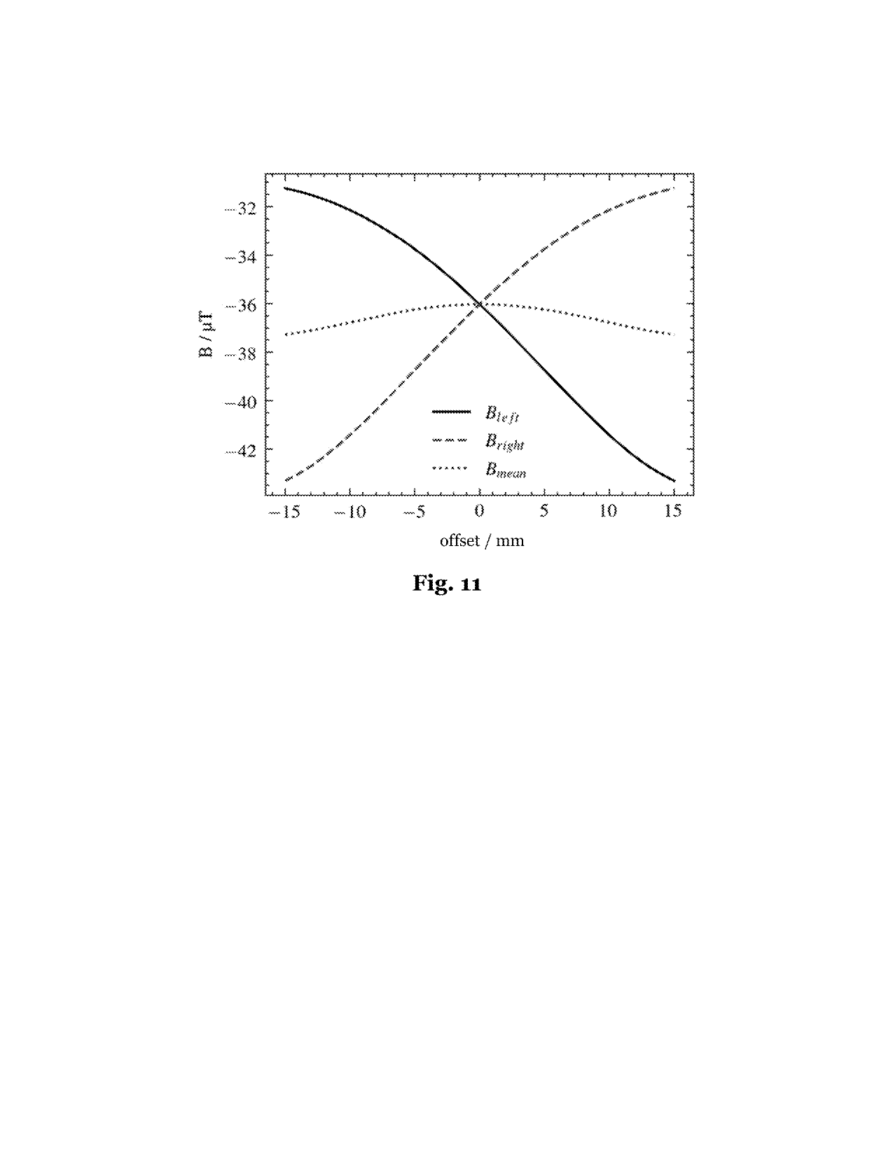

As shown in FIG. 10, an offset of the elongated electrical conductor 14 to the axis A of mirror symmetry may be determined from the ratio of the magnetic field strengths at two positions which are mirror-symmetrical with respect to the axis A of mirror symmetry. The determined offset may be used, as illustrated by FIG. 11, to determine, based on a calibration curve, the magnetic field strength that would have been measured if there had been no offset between the elongated electrical conductor 14 and the axis A of mirror symmetry.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for compensating for an influence of a position of an elongated electrical conductor on a measurement of an intensity of a current flow along the elongated electrical conductor by a magnetic field sensor, the method comprising:
providing a magnetically permeable structure surrounding the elongated electrical conductor, a cross-section of the magnetically permeable structure exhibits an axis of mirror symmetry or the cross-section of the magnetically permeable structure exhibits an axis of mirror symmetry at least in an area around the elongated electrical conductor, a longitudinal axis of a section of the elongated electrical conductor surrounded by the magnetically permeable structure being substantially perpendicular to the axis of mirror symmetry; and
measuring magnetic field strengths at two positions offset from each other substantially parallel to the axis of mirror symmetry and using the magnetic field strengths to compensate for the influence of an offset of the elongated electrical conductor substantially parallel to the axis of mirror symmetry on the measurement.

2. The method according to claim 1, wherein the area of the cross-section around the elongated electrical conductor, which exhibits the axis of mirror symmetry, comprises more than 50%, more than 75% or more than 90% of a cross-sectional area of the magnetically permeable structure.

3. The method according to claim 1, wherein the magnetically permeable structure encloses the elongated electrical conductor only partially.

4. The method according to claim 1, wherein the magnetically permeable structure has a U-shaped cross-section.

5. The method according to claim 4, wherein the magnetically permeable structure comprises a housing having a cross-section with a V-shaped recess, and wherein the elongated electrical conductor extends through the V-shaped recess.

6. The method according to claim 1, further comprising: measuring magnetic field strengths at two positions which are mirror-symmetrical with respect to the axis of mirror symmetry and using the magnetic field strengths to compensate for the influence of an offset of the elongated electrical conductor substantially perpendicular to the axis of mirror symmetry on the measurement.

7. The method according to claim 6, further comprising: compensating for the influence of magnetic interference fields by adding each of the magnetic field strengths at the two positions offset from each other parallel to the axis of mirror symmetry to a magnetic field strength at the respective mirror-symmetric position.

8. An apparatus for measuring an intensity of a current flow along an elongated electrical conductor, the apparatus comprising:
a magnetically permeable structure surrounding the elongated electrical conductor, a cross-section of the magnetically permeable structure exhibits an axis of mirror symmetry or the cross-section of the magnetically permeable structure exhibits an axis of mirror symmetry at least in an area around the elongated electrical conductor, wherein a longitudinal axis of a section of the elongated electrical conductor surrounded by the magnetically permeable structure is substantially perpendicular to the axis of mirror symmetry;
a first magnetic field sensor; and
a second magnetic field sensor, the first and second magnetic field sensors being offset from each other substantially parallel to the axis of mirror symmetry or arranged mirror-symmetrically to the axis of mirror symmetry.

9. The apparatus according to claim 8, wherein an area of the cross-section around the electrical conductor in which the axis of mirror symmetry is exhibited comprises more than 50%, more than 75% or more than 90% of a cross-sectional area of the magnetically permeable structure.

10. The apparatus according to claim 8, wherein the magnetically permeable structure encloses the elongated electrical conductor only partially.

11. The apparatus according to claim 8, wherein the magnetically permeable structure has a U-shaped cross-section.

12. The apparatus according to claim 11, wherein the magnetically permeable structure comprises a housing having a cross-section with a V-shaped recess, and wherein the elongated electrical conductor extends through the V-shaped recess.

13. The apparatus according to claim 11, wherein the first and second magnetic field sensors are configured to measure a magnetic field strength substantially perpendicular to a surface of the magnetically permeable structure facing the elongated electrical conductor.

14. The apparatus according to claim 8, further comprising:
a third magnetic field sensor,
wherein the first magnetic field sensor and the second magnetic field sensor are arranged mirror-symmetrically with respect to the axis of mirror symmetry; and
wherein the third magnetic field sensor is offset relative to the first magnetic field sensor substantially parallel to the axis of mirror symmetry.

15. The apparatus according to claim 14, further comprising:
a fourth magnetic field sensor,
wherein the third magnetic field sensor and the fourth magnetic field sensor are arranged mirror-symmetrically with respect to the axis of mirror symmetry; and
wherein the fourth magnetic field sensor is offset relative to the second magnetic field sensor substantially parallel to the axis of mirror symmetry.

16. The apparatus according to claim 15, further comprising:
a fifth magnetic field sensor,
wherein the fifth magnetic field sensor is offset relative to the first and third magnetic field sensors substantially parallel to the axis of mirror symmetry.

17. The apparatus according to claim 16, further comprising:
a sixth magnetic field sensor,
wherein the fifth magnetic field sensor and the sixth magnetic field sensor are arranged mirror-symmetrically with respect to the axis of mirror symmetry; and
wherein the sixth magnetic field sensor is offset relative to the second and fourth magnetic field sensors substantially parallel to the axis of mirror symmetry.
